(19) United States
(12) Patent Application Publication
(10) Pub. No.: US 2009/0254784 A1
(43) Pub. Date: Oct. 8, 2009

(54) SEMICONDUCTOR MEMORY DEVICE AND SYSTEM USING SEMICONDUCTOR MEMORY DEVICE

(75) Inventors: MASATOSHI SONODA, KANAGAWA (JP); YUUJIROU SHIMIZU, KANAGAWA (JP); HIDEAKI ARIMA, KANAGAWA (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 12/420,204

(22) Filed: Apr. 8, 2009

(30) Foreign Application Priority Data
Apr. 8, 2008 (JP) 2008-100145

(51) Int. Cl. G11C 29/04; G06F 11/22

(52) U.S. Cl. 714/718; 714/E11.145; 712/208; 712/214

(57) ABSTRACT

A semiconductor memory device comprises a RAM (Random Access Memory), an ODT (On-Die Termination) circuits and a JTAG (Joint Test Action Group) circuit. The RAM is connected to a data input-output port. The ODT circuit is provided between the data input-output port and a termination port. The JTAG circuit controls the ODT circuit in response to an instruction such that the data input-output port and the termination port are electrically connected with each other.

### INCORPORATION BY REFERENCE

This application is based upon and claims the benefit of priority from Japanese patent application No. 2008-100145, filed on Apr. 8, 2008, the disclosure of which is incorporated herein in its entirely by reference.

### BACKGROUND OF THE INVENTION

1. Field of the Invention

The present invention relates to a semiconductor memory device comprising a RAM (Random Access Memory) and a system using the semiconductor memory device.

2. Description of Related Art

An SRAM (Static Random Access Memory) is generally provided with a memory core, a read write control circuit and a data input-output circuit. Data is read from and written to the memory core as a RAM. The read write control circuit receives commands (e.g. Read, Write, NOP (Non-operate)) and address information through command/address ports, and controls read and write to the memory core. The data input-output circuit transfers data between the memory core and a data input-output port.

The SRAM is further provided with a JTAG (Joint Test Action Group) circuit. The JTAG circuit is used for testing the SRAM after mounted on a board The JTAG; circuit is described in, for example, Japanese Laid-Open Patent Application JP-2004-294397.

Meanwhile, a clock frequency required for the SRAM becomes higher and higher with recent progress in performance of applications. Moreover, the Double Data Rate (DDR) method has become popular for performing a data input-output operation, and currently a data transfer rate exceeding 500 MHz is widely adopted. Because of these aspects, improvement in quality of a signal line on the board has been demanded.

To that end, in a case of a set using a high-speed SRAM, a termination resistance is generally provided on the board in order to suppress reflection during a high frequency operation.

The inventors of the present application have recognized the following points. To provide the termination resistance on the board is often disadvantageous in terms of area and cost, especially in a set using an SRAM having a large number of input-output ports. In a case of a DRAM where an ASIC and memories are often connected on a one-to-many basis, the memory is often provided with an ODT (On-Die Termination) function wherein the ODT function is ON/OFF controlled by the use of a mode register. However, a typical SRAM is not provided with a mode register. It is therefore necessary to provide the SRAM with dedicated ON/OFF pins as the ODT function or a mode register, which greatly influences not only the memory but also the ASIC and the board design.

### SUMMARY

In one embodiment of the present invention, a semiconductor memory device comprises a RAM (Random Access Memory), an ODT (On-Die Termination) circuit, and a JTAG (Joint Test Action Group) circuit. The RAM is connected to a data input-output port. The ODT circuit is provided between the data input-output port and a termination port. The JTAG circuit controls the ODT circuit in response to an instruction such that the data input-output port and the termination port are electrically connected with each other.

In the semiconductor memory device thus constructed, the JTAG circuit mounted together with the RAM can be used for controlling the ODT circuit such that the data input-output port and the termination port are electrically connected with each other. It is therefore possible to achieve ON/OFF control of the ODT circuit without providing the RAM with new pins (ports) or a mode register.

In another embodiment of the present invention, a system comprises the above-described semiconductor memory device and an instruction issuing unit. The instruction issuing unit issues the instruction and outputs the instruction to the semiconductor memory device.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a block diagram showing a configuration of a semiconductor memory device and a system using the semiconductor memory device according to an embodiment of the present invention; and

FIG. 2 is a block diagram showing a configuration of a JTAG circuit described in Japanese Laid-Open Patent Application JP-2004-294397, and is used for explaining a basic operation (JTAG function) of the JTAG circuit according to the embodiment of the present invention.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

[Configuration]

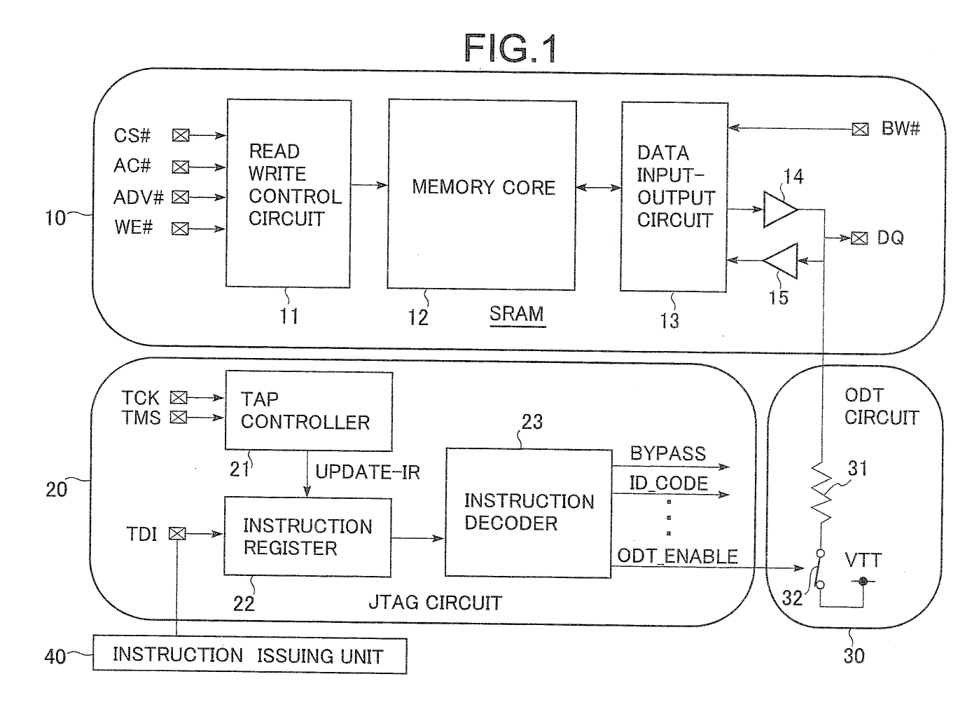

FIG. 1 shows a configuration of a semiconductor memory device and a system using the semiconductor memory device according to an embodiment of the present invention. The semiconductor memory device (memory chip) is provided with an SRAM (Static Random Access Memory) 10, a JTAG (Joint Test Action Group) circuit 20 and an ODT (On-Die Termination) circuit 30. The JTAG circuit 20 is used for testing the SRAM 10 after mounted on a board.

The SRAM 10 is connected to a data input-output port DQ. The SRAM 10 has a read write control circuit 11, a memory core 12 and a data input-output unit. Data is read from and written to the memory core 12 as a RAM.

The read write control circuit 11 is connected between command/address ports (CS#, AC#, ADV# and WE#) and the memory core 12. For example, a chip select command and a write enable command are respectively input to the port CS# and WE# among the command/address ports. The read write control circuit 11 receives commands (e.g. Read, Write, NOP (Non-operate)) and address information through the command/address ports CS#, AC#, ADV# and WE#, and controls read and write to the memory core 12.

The data input-output unit is connected between the memory core 12 and an external port BW# and the data input-output port DQ. The data input-output unit includes a data input-output circuit 13 and buffers 14 and 15. The data input-output circuit 13 is connected to the memory core 12, the external port BW#, an input of the buffer 14 and an output of the buffer 15. An output of the buffer 14 and an input of the buffer 15 are connected to the data input-output port DQ. The data input-output unit (13 to 15) transfers data between the memory core 12 and the data input-output port DQ.

The JTAG circuit 20 has a TAP controller 21, an instruction register 22 and an instruction decoder 23.

The TAP controller 21 is connected to external ports TCK and TMS. The instruction register 22 is connected to the TAP controller 21 and an external port TDI. The instruction decoder 23 is connected to the instruction register 22 and the ODT circuit 30

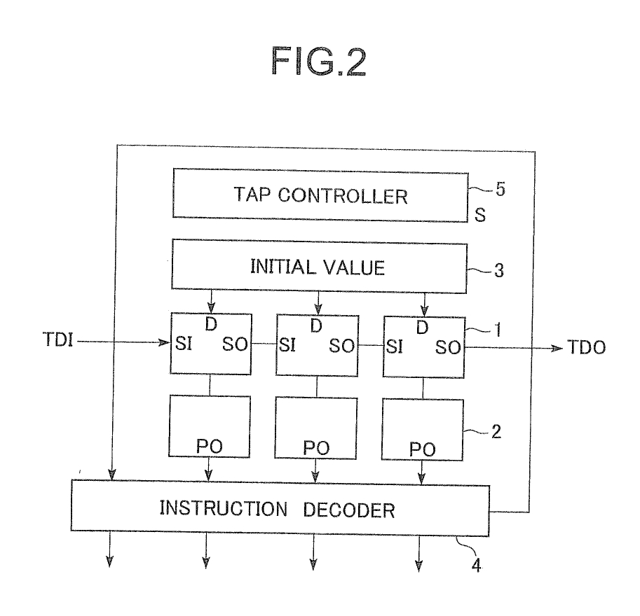

A basic operation (JTAG function) of the JTAG circuit 20 is described for example, in the above-mentioned patent document (Japanese Laid-Open Patent Application JP-2004-294397). FIG. 2 schematically shows a configuration of a JTAG circuit described in the patent document. The JTAG circuit shown in FIG. 2 has a TAP controller 5, a holding unit that holds an initial value 3, a shift register 1, an output latch 2 and an instruction decoder 4. The TAP controller 21 of the JTAG circuit 20 corresponds to the TAP controller 5 described in the patent document. The instruction register 22 of the JTAG circuit 20 corresponds to the initial value 3, shift register 1 and output latch 2 described in the patent document. The instruction decoder 23 of the JTAG circuit 20 corresponds to the instruction decoder 4 described in the patent document.

Signals supplied to the external ports TCK, TMS and TDI are default signals for the JTAG circuit, details of which are specified in the IEEE Standard 1149.1-2001. As shown in FIG. 1, an instruction issuing unit 40 that is realized by hardware and/or software is connected to the external port TDI. Preferably, the instruction issuing unit 40 is software-based and operates in accordance with software. The instruction issuing unit 40 issues an instruction (instruction code) and outputs the instruction as the default signal to the instruction register 22 of the JTAG circuit through the external port TDI. A state of the TAP controller 21 is set to “Shift-IR”, “Clock-IR”, “Update-IR” or the like depending on inputs to the external ports TCK and TMS. The “Shift-IR”, “Clock-IR” and “Update-IR” are default states for the JTAG, details of which are specified in the IEEE Standard 1149.1-2001.

The JTAG circuit 20 controls a test mode by using the JTAG function. When entering a test mode, the TAP controller 21 is first set to the “Shift-IR”. Then, an instruction code is input to the instruction register 22 (corresponding to the initial value 3) through the external port TDI. When the TAP controller 21 is set to the “Update-IR” under this condition, the instruction register 22 (corresponding to the shift register 1) retrieves the instruction code. Then, the instruction register 22 (corresponding to the output latch 2) outputs that instruction code. The instruction decoder 23 decodes the instruction code output from the instruction register 22 and thereby outputs “BYPASS” and “ID_code”. In this manner, the device can enter the desired test mode.

Furthermore, the JTAG circuit 20 controls the ODT circuit 30 in response to an instruction (instruction code) such that the data input-output port DQ and a termination voltage port VTT are electrically connected with each other. More specifically, the instruction decoder 23 of the JTAG circuit 20 decodes the instruction (instruction code) output from the instruction register 22 and thereby outputs an ODT enable signal ODT_enable to the ODT circuit 30. That is, the JTAG circuit 20 outputs the ODT enable signal ODT_enable to the ODT circuit 30, in response to the instruction (instruction code) input through the external port TDI.

The ODT circuit 30 is connected between the data input-output port DQ and the termination voltage port VTT. The ODT circuit 30 has a termination resistance 31 and a switch 32.

One end of the termination resistance 31 is connected to the SRAM 10 and the data input-output port DQ. The other end of the termination resistance 31 is connected to the termination voltage port VTT through the switch 32. The termination resistance 31 is provided in order to improve quality of signal lines with respect to the data input-output unit (13 to 15).

The switch 32 is provided between the other end of the termination resistance 31 and the termination voltage port VTT. A termination voltage is applied to the termination voltage port VTT. The switch 32 is a transfer gate including an N-type MOS transistor and a P-type MOS transistor. The switch 32 is turned ON in response to the above-mentioned ODT enable signal ODT_enable, and thereby the termination resistance 31 and the termination voltage port VTT are electrically connected with each other. That is to say, the data input-output port DQ and the termination voltage port VTT are electrically connected with each other through the termination resistance 31. Consequently, the termination is provided to a transmission line connected to the data input-output port DQ.

In the ODT circuit 30 shown in FIG. 1, a resistance element (the termination resistance 31) is connected to the termination voltage port VTT through the switch 32. It should be noted that the configuration of the ODT circuit 30 is not limited to that. The present invention is applicable regardless of the configuration of the ODT circuit. For example, a Thevenin termination may be used as a termination port instead of the above-mentioned termination voltage port VTT.

[Operation]

An operation of the system and the semiconductor memory device will be described below with reference to FIG. 1.

In a test logic reset (initial state) of the JTAG circuit 20, the instruction issuing unit 40 does not issue the instruction (instruction code). In other words, the instruction code is not output. In this case, the switch 32 of the ODT circuit 30 is turned OFF.

Next, when entering the test mode, the TAP controller 21 of the JTAG circuit 20 is set to the “Shift-IR”. The instruction issuing unit 40 issues an instruction (instruction code) and outputs the instruction to the instruction register 22 of the JTAG circuit 20 through the external port TDI. Then, the TAP controller 21 is set to the “Update-IR”, and the instruction code is output from the instruction register 22. The instruction decoder 23 decodes the instruction code output from the instruction register 22 and thereby outputs the “BYPASS” and “ID_code” to enter the desired test mode. Moreover, the instruction decoder 23 outputs the ODT enable signal ODT_enable to the ODT circuit 30. The switch 32 of the ODT circuit 30 is turned ON in response to the ODT enable signal ODT_enable, and thus the data input-output port DQ and the termination voltage port VTT are electrically connected with each other through the termination resistance 31. This state remains valid until the JTAG circuit 20 executes the “Update-IR” when an instruction associated with other than the ODT enable signal ODT_enable is newly input thereto.

### ADVANTAGEOUS EFFECTS

In the semiconductor memory device according to the present embodiment, the JTAG circuit 20 mounted together with the SRAM 10 can be used for controlling the ODT circuit 30 such that the data input-output port DQ and the termination voltage port VTT are electrically connected with each other. It is therefore possible to achieve ON/OFF control of the ODT circuit 30 without providing the SRAM 10 with new pins (ports) or a mode register.

Also, according to the present embodiment, a semiconductor memory device (the SRAM 10 and JTAG circuit 20) without the ODT function can be achieved by turning OFF the switch 32 in the ODT circuit 30, for example, during the test logic reset. On the other hand, a semiconductor memory device (the SRAM 10, JTAG circuit 20 and ODT circuit 30) provided with the ODT function can be achieved by turning ON the switch 32 in the ODT circuit 30, for example, when entering the test mode. In this manner, the semiconductor memory device according to the present embodiment can be switched between the semiconductor memory device without the ODT function and the semiconductor memory device with the ODT function.

Furthermore, the instruction issuing unit 40 of the system can be realized based on software. In other words, the instruction issuing unit 40 is software-based and operates in accordance with the software. In this case, the switching between the semiconductor memory device without the ODT function and the semiconductor memory device with the ODT function can be achieved by the software.

It is apparent that the present invention is not limited to the above embodiments and may be modified and changed without departing from the scope and spirit of the invention.

What is claimed is:

1. A semiconductor memory device comprising:
a random access memory connected to a data input-output port;
an on-die termination circuit provided between said data input-output port and a termination port; and
a joint test action group circuit configured to control said on-die termination circuit in response to an instruction such that said data input-output port and said termination port are electrically connected with each other.

2. The semiconductor memory device according to claim 1,
wherein said random access memory is a static random access memory.

3. The semiconductor memory device according to claim 2,
wherein said static random access memory comprises:
a memory core; and
a data input-output unit connected between said memory core and said data input-output port and configured to transfer data between said memory core and said data input-output port.

4. The semiconductor memory device according to claim 1,
wherein said on-die termination circuit comprises:
a termination resistance whose one end is connected to said random access memory and said data input-output port; and
a switch provided between the other end of said termination resistance and said termination port and configured to be turned on in response to an enable signal such that said data input-output port and said termination port are electrically connected with each other through said termination resistance,
wherein said joint test action group circuit outputs said enable signal in response to said instruction.

5. The semiconductor memory device according to claim 1,
wherein said instruction is not issued during a test logic reset of said joint test action group circuit.

6. A system comprising:
a semiconductor memory device; and
an instruction issuing unit configured to issue an instruction and output said instruction to said semiconductor memory device,
wherein said semiconductor memory device comprises:
a random access memory connected to a data input-output port;
an on-die termination circuit provided between said data input-output port and a termination port; and
a joint test action group circuit configured to control said on-die termination circuit in response to said instruction such that said data input-output port and said termination port are electrically connected with each other.

7. The system according to claim 6,
wherein said random access memory is a static random access memory.

8. The system according to claim 6,
wherein said on-die termination circuit comprises:
a termination resistance whose one end is connected to said random access memory and said data input-output port; and
a switch provided between the other end of said termination resistance and said termination port and configured to be turned on in response to an enable signal such that said data input-output port and said termination port are electrically connected with each other through said termination resistance,
wherein said joint test action group circuit outputs said enable signal in response to said instruction.

9. The system according to claim 6,
wherein said instruction issuing unit does not issue said instruction during a test logic reset of said joint test action group circuit.

10. The system according to claim 6,
wherein said instruction issuing unit is software-based.
